(19) United States
(12) Patent Application Publication
(10) Pub. No.: US 2015/0241915 A1
(43) Pub. Date: Aug. 27, 2015

(54) CONDUCTIVE STRUCTURES FOR A FLEXIBLE SUBSTRATE IN A WEARABLE DEVICE

(71) Applicants: Dileep Goyal, Fremont, CA (US); Mihai Ionescu, Santa Cruz, CA (US); Hari N. Chakravarthula, San Jose, CA (US)

(72) Inventors: Dileep Goyal, Fremont, CA (US); Mihai Ionescu, Santa Cruz, CA (US); Hari N. Chakravarthula, San Jose, CA (US)

(73) Assignee: AliphCom, San Francisco, CA (US)

(21) Appl. No.: 14/541,134

(22) Filed: Nov. 13, 2014

Related U.S. Application Data
(60) Provisional application No. 61/903,954, filed on Nov. 13, 2013.

(51) Int. Cl. G06F 1/16; H05K 3/30; A41D 20/00

(52) U.S. Cl. CPC G06F 1/163; A41D 20/00; H05K 3/30

(57) ABSTRACT

Embodiments relate generally to wearable electrical and electronic hardware, computer software, wired and wireless network communications, and to wearable/mobile computing devices. More specifically, various embodiments are directed to, for example, conductive structures for a flexible substrate, a component coupled to the flexible substrate, and/or a wearable device. In one example, a wearable device includes a framework configured to be worn or attached, and a flexible substrate coupled to the framework. In some examples, the flexible substrate may have a first end and a second end, and may include one or more resilient conductive structures, and one or more rigid regions configured to receive one or more components including a sensor, or, for example, electrodes for a bioimpedance sensor.

### RELATED APPLICATIONS

This application claims the benefit of U.S. Provisional Patent Application No. 61/903,954 filed Nov. 13, 2013 with Attorney Docket No. ALI-345P, which is herein incorporated by reference. This application incorporates the following applications herein by reference: U.S. patent application Ser. No. 13/942,503 filed Jul. 13, 2013 with Attorney Docket No. ALI-001CIP1CIP1CON1CON1, U.S. patent application Ser. No. 14/______ filed Nov. 13, 2014 with Attorney Docket No. ALI-344 titled “FLEXIBLE SUBSTRATE FOR A WEARABLE DEVICE,” and U.S. patent application Ser. No. 14/______ filed Nov. 13, 2014 with Attorney Docket No. ALI-346 titled “ALIGNMENT OF COMPONENTS COUPLED TO A FLEXIBLE SUBSTRATE FOR WEARABLE DEVICES, and U.S. patent application Ser. No. 14/480,628 (ALI-516) filed on Sep. 8, 2014.

### FIELD

Embodiments relate generally to wearable electrical and electronic hardware, computer software, wired and wireless network communications, and to wearable/mobile computing devices. More specifically, various embodiments are directed to, for example, conductive structures for a flexible substrate or components thereof.

### BACKGROUND

Conventional wearable devices, such as data capable bands or wrist bands, typically require circuit boards to be formed from flexible materials. However, some conductors implemented in, or in association with, flexible materials are not well-suited to provide sufficient connectivity or reliability for conveying communication signals among electronic devices, such as semiconductor devices, that are mounted on the flexible material. One approach implements straight strands of copper wire in an insulation material. While functional, the above-described conductor may be sub-optimal, especially when experiencing forces applied to the conductors when the wearable device is worn, or when the device is being put on or removed from a user.

Thus, what is needed is a solution for implementing conductive structures for a flexible substrate without the limitations of conventional techniques.

### BRIEF DESCRIPTION OF THE DRAWINGS

Various embodiments or examples (“examples”) of the invention are disclosed in the following detailed description and the accompanying drawings:

FIG. 1 illustrates an example of resilient conductive structures implemented in a flexible substrate, according to some embodiments;

FIGS. 2 and 3 depict examples of a resilient conductive structure used in association with a flexible substrate, according to some examples;

FIG. 4 is a diagram that shows an example of a reinforced redundant conductor implemented in a flexible substrate, according to some examples;

FIG. 5 is a diagram that shows another example of a reinforced redundant conductor, according to some examples;

FIG. 6 is a specific example of a reinforced redundant conductor, according to some examples;

FIG. 7 is a diagram showing a side view of a flexible substrate including components coupled to a framework, according to some examples;

FIG. 8 is an example of a flow for implementing a flexible substrate including resilient conductive structures and/or reinforced redundant conductors, according to some embodiments;

FIG. 9 is a diagram depicting of a flexible substrate implementing resilient conductive structures in an electrode bus, according to some examples;

FIG. 10 is a diagram depicting of a flexible substrate implementing resilient conductive structures in an electrode bus, according to some examples; and

FIG. 11 is a diagram depicting an example of a wearable device implementing resilient conductive structures, according to some embodiments.

### DETAILED DESCRIPTION

Various embodiments or examples may be implemented in numerous ways, including as a system, a process, an apparatus, a user interface, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For clarity, technical material that is known in the technical fields related to the examples has not been described in detail to avoid unnecessarily obscuring the description.

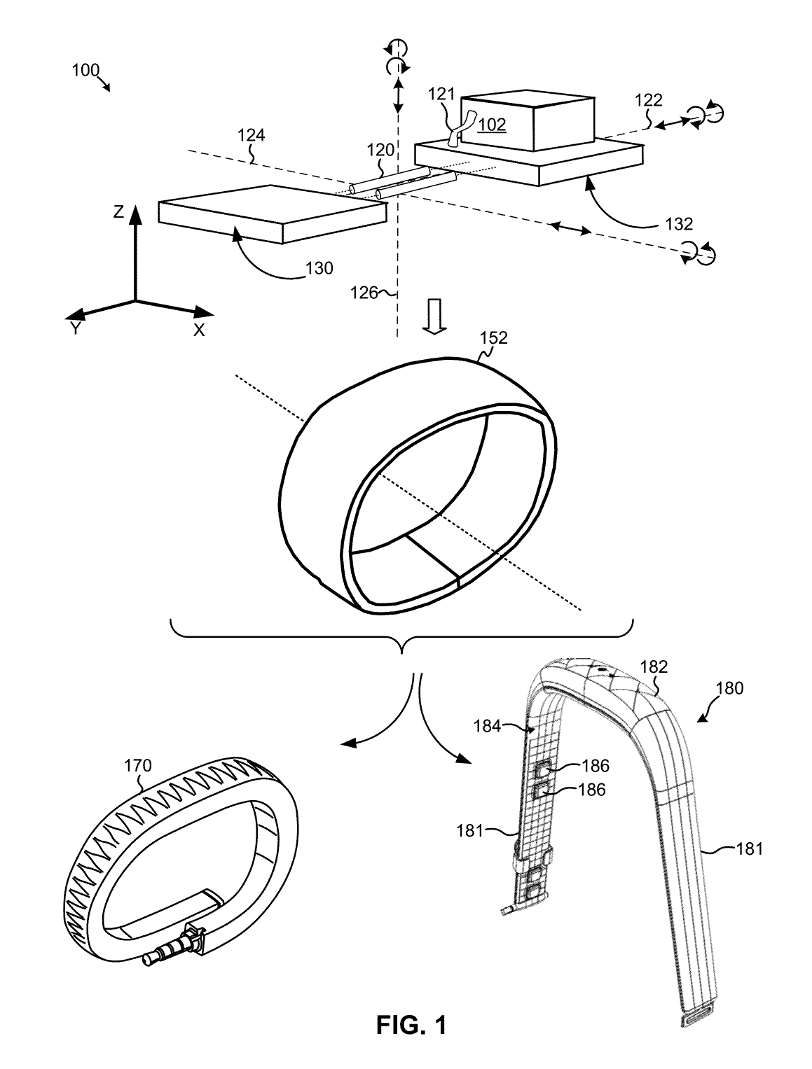

FIG. 1 illustrates an example of resilient conductive structures implemented in a flexible substrate, according to some embodiments. Diagram 100 depicts rigid regions 130 and 132 of a flexible substrate (not shown) in which resilient conductive structures 120 couple devices associated with rigid regions 130 and 132 to exchange data signals. In some examples, resilient conductive structures 121 can couple a device 102 to a rigid region 132, which can include conductive paths, other devices, and/or circuitry. Diagram 100 further depicts examples of a number of forces associated with axes 122, 124, and 126 that resilient conductive structures 120 and 121 may experience during use of a wearable device 170. As depicted in diagram 100, rigid regions 130 and 132 of a flexible substrate (and components 102 mounted thereupon) are coupled to framework 152 to form a constituent part of the wearable device 170. Framework 152 can be configured to be formed in any shape, such as an ellipse, a circle, and/or in a helical shape, so that wearable device 170 can be worn around a wrist or other appendage of a user. Wearable device 170 can be formed when flexible substrate 120 and framework 152 are overmolded. In some examples, device 102 can be a vibratory motor, whereby resilient conductive structure 121 may experience mechanical vibrations that otherwise might give rise to a failure in a conductor due to stress cracks over repeated and cyclical use. Resilient conductive structure 121 is configured to maintain conductivity when subjected to vibrations and other mechanical forces that it experiences.

Framework 152, in some examples, may include at least interior structures of a wearable pod 182 or may include a cradle structure as described in U.S. patent application Ser. No. 14/480,628 (ALI-516) filed on Sep. 8, 2014, which is herein incorporated by reference.

In some examples, as depicted in diagram 100, flexible substrate 120 and its components mounted thereupon are coupled to framework 152 to form a constituent part of a wearable device 180. In the example shown, wearable device 180 may include a wearable pod 182 that can include logic, including processors and memory, configured to detect, among other things, physiological signals via bioimpedance signals. In one example, wearable pod 182 can include bioimpedance circuitry configured to drive bioimpedance through one electrode 186 disposed in a band or strap 181. Strap 181 may be integrated or removable coupled to wearable pod 182.

One or more flexible substrates (not shown) may include conductive materials disposed in interior 184 of band or strap 181 to, for example, couple electrodes 186 to logic (or any other component) in wearable pod 182 or any other portion of wearable device 180. In at least one example, electrodes 186 can be implemented to facilitate transmission of bioimpedance signals to determine physiological signals or characteristics, such as heart rate. Further, electrodes 186 may also be coupled via a flexible substrate to a galvanic skin response (“GSR”) logic circuit.

A wearable pod and/or wearable device may be implemented as data-mining and/or analytic device that may be worn as a strap or band around or attached to an arm, leg, ear, ankle, or other bodily appendage or feature. In other examples, a wearable pod and/or wearable device may be carried, or attached directly or indirectly to other items, organic or inorganic, animate, or static. Note, too, that wearable pod enough be integrated into or with a strap 181 or band and can be shaped other than as shown. For example, a wearable pod circular or disk-like in shape with a display portion disposed on one of the circular surfaces.

According some embodiments, logic disposed in wearable pod (or disposed anywhere in wearable device, such as in strap 181) may include a number of components formed in either hardware or software, or a combination thereof, to provide structure and/or functionality therein. In particular, the logic may include a touch-sensitive input/output (“I/O”) controller to detect contact with portions of a pod cover or interface, a display controller to facilitate emission of light, an activity determinator configured to determine an activity based on, for example, sensor data from one or more sensors (e.g., disposed in an interior region within wearable pod 182, or disposed externally). A bioimpedance (“BI”) circuit may facilitate the use of bioimpedance signals to determine a physiological signal (e.g., heart rate), and a galvanic skin response (“GSR”) circuit may facilitate the use of signals representing skin conductance. A physiological (“PHY”) signal determinator may be configured to determine physiological characteristic, such as heart rate, among others, and a temperature circuit may be configured to receive temperature sensor data to facilitate determination of heat flux or temperature. A physiological (“PHY”) condition determinator may be configured to implement heat flux or temperature, or other sensor data, to derive values representative of a condition (e.g., a biological condition, such as caloric energy expended or other calorimetry-related determinations). Logic can include a variety of other sensors and other logic, processors, and/or memory including one or more algorithms.

Examples of wearable device 180 and one or more components, including flexible substrates and/or conductive structures, as well as electrodes, may be described in U.S. patent application Ser. No. 14/480,628 (ALI-516) filed on Sep. 8, 2014, which is herein incorporated by reference.

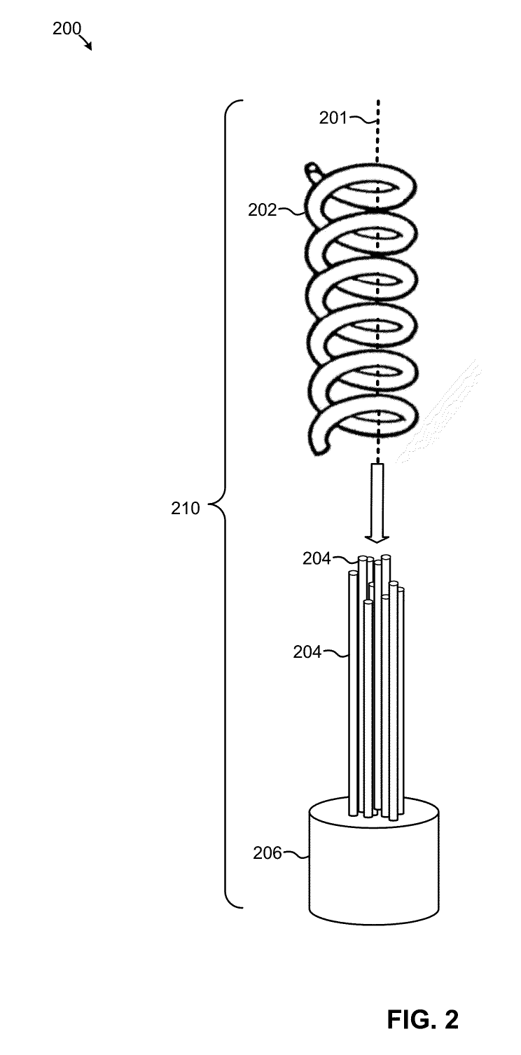

FIGS. 2 and 3 depict examples of a resilient conductive structure used in association with a flexible substrate, according to some examples. Diagram 200 of FIG. 2 depicts an example of a resilient conductive structure 210 includes a conductor 202 configured to vary (e.g., in direction, distance, etc.) from a medial line 201 as conductor 202 traverses or otherwise extends a length of resilient conductive structure 210. Portions of conductor 202 can form portions of a coil conductor, as shown. Note that conductor 202 is not limited to a coil, but rather can have other shapes, and can be folded around medial line 201. Conductor 202 can be a foil conductor, a circular wire conductor, or a conductor having any other shape. Further, conducted 202 is formed or otherwise wrapped around a core (e.g., a non-conductive core) that can include a number of fibers 204. In some examples, fiber 204 can include Kevlar® fibers or Kevlar-like fibers, as well as Aramid fibers to enhance rigidity and reliability of resilient conductive structure 210. In some cases, conductor 202 can be composed of a tin-coated copper material. Further, conductor 202 and fibers 204 can be encapsulated in an insulation material 206, such as silicone rubber.

FIG. 3 depicts another example of a resilient conductive structure, according to another example. Diagram 300 shows a number of conductors 302a, 302b, and 302c that are formed around the plurality of fibers 304, all which is encapsulated in an insulating material 306. In this example, conductors 302a, 302b, and 302c can be wrapped around the number of fibers 304 as interleaved coils that either can be disposed separately (e.g., separated by a distance from each other) or can be in electrical contact with each other. According to the example shown, the number of conductors 302a, 302b, and 302c provides a degree of redundancy should one or more conductors 302a, 302b, and 302c fail due to exposure to repeated or cyclical stresses. Note that while only three conductors are shown, any number of conductors can be implemented to form resilient conductive structure 310. As such, resilient conductive structure 310 can include multiple conductors that traverse the length of resilient conductive structure 310 to provide connective redundancy for each other.

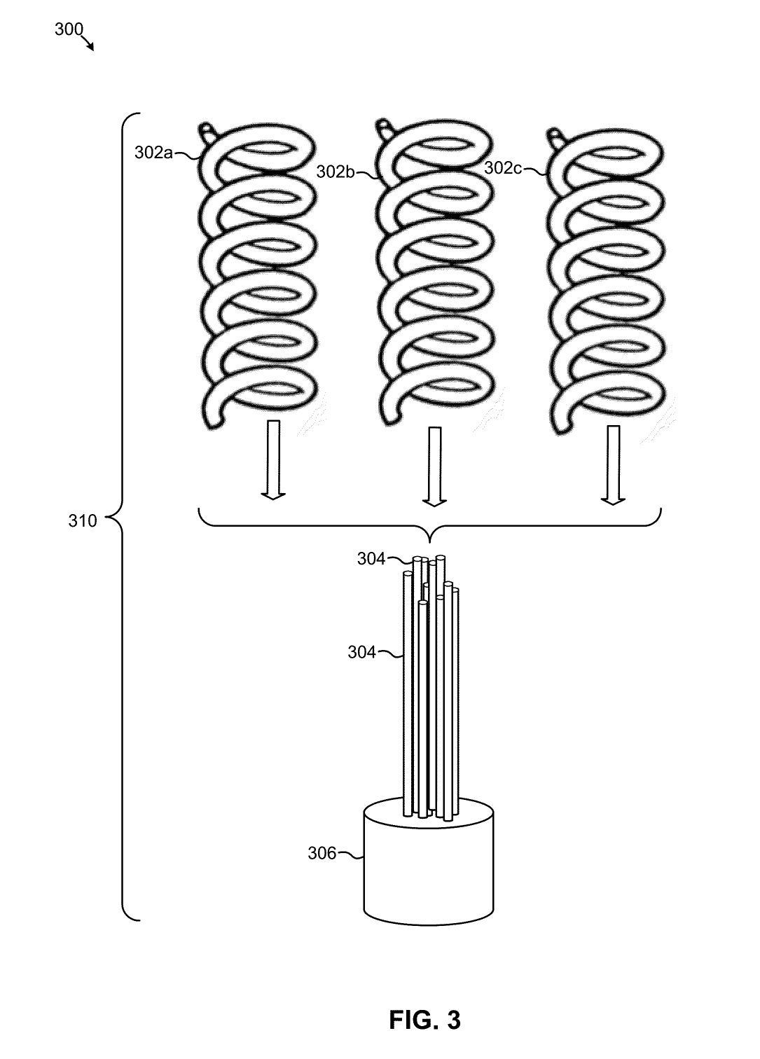

FIG. 4 is a diagram that shows an example of a reinforced redundant conductor implemented in a flexible substrate, according to some examples. Diagram 400 depicts a flexible substrate 402 including a number of conductors 404, which can be traces, and a reinforced redundant conductor 410. Also shown is a rigid region 401 upon which a device or vibratory motor can be disposed. In use, flexible substrate 402 may experience forces that are applied to a side area 409 that introduce stresses orthogonal or substantially orthogonal to the elongated lengths of traces 404 and reinforced redundant conductor 410. Note that in some cases reinforced redundant conductor 410 can be disposed adjacent to an edge of flexible substrate 402 to operate, at least in part, as a buffer.

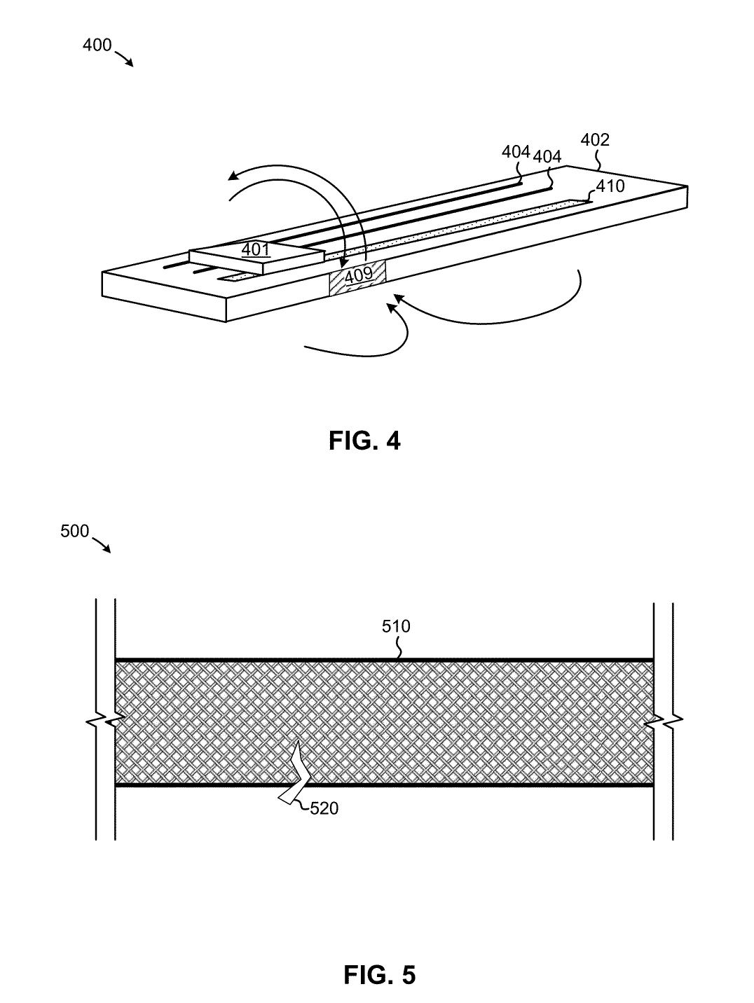

FIG. 5 is a diagram that shows an example of a reinforced redundant conductor, according to some examples. Diagram 500 depicts a reinforced redundant conductor 510 as a mesh-like structure formed of a conductive material that provides a level of redundancy and enhanced stress relief. To illustrate, consider a stress fracture 520 that is propagating from one edge. The absence of conductors, such as a hole, provides a structure for reducing stresses that otherwise might exacerbate the propagation of stress fracture 520. While the holes in the mesh are shown as rectangular, they need not be. In some cases the holes can be circular.

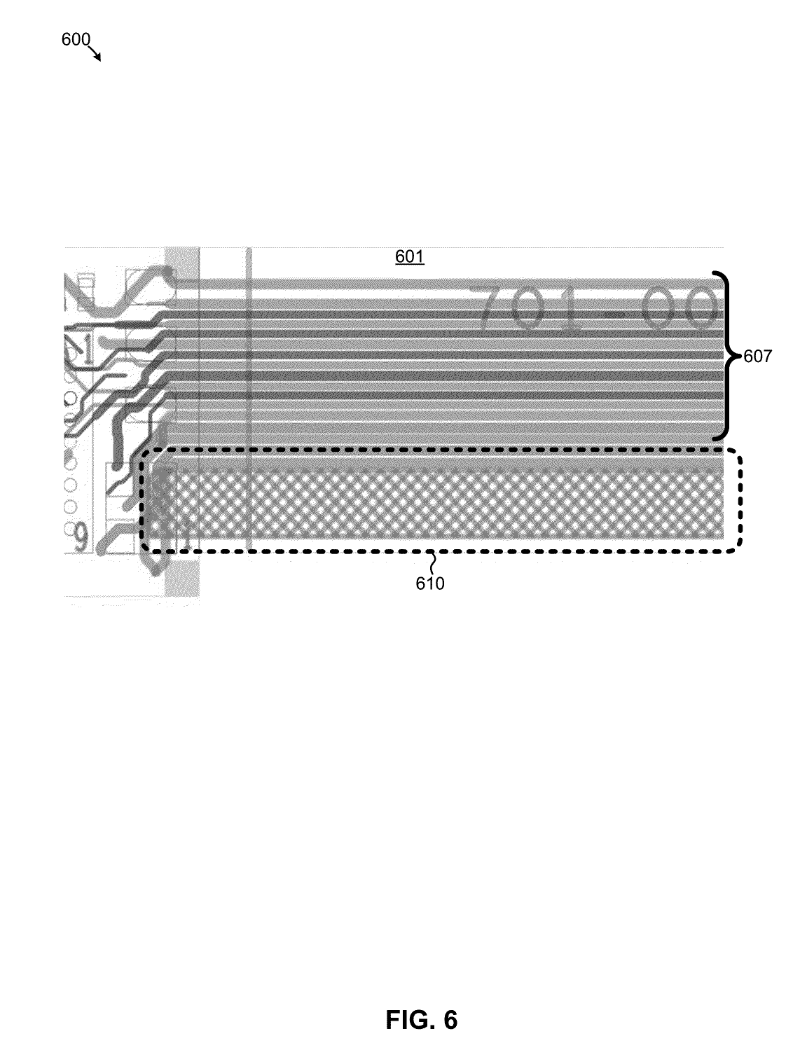

FIG. 6 is a specific example of a reinforced redundant conductor, according to some examples. Diagram 600 is a top view of a flexible substrate, and depicts a reinforced redundant conductor 610 adjacent an edge of flexible substrate 601. As reinforced redundant conductor 610 is disposed near the edge that may receive mechanical forces and/or stresses, reinforced redundant conductor 610 also may protect other conductors or traces 607 from receiving the magnitude of stress or forces that is applied to reinforced redundant conductor 610.

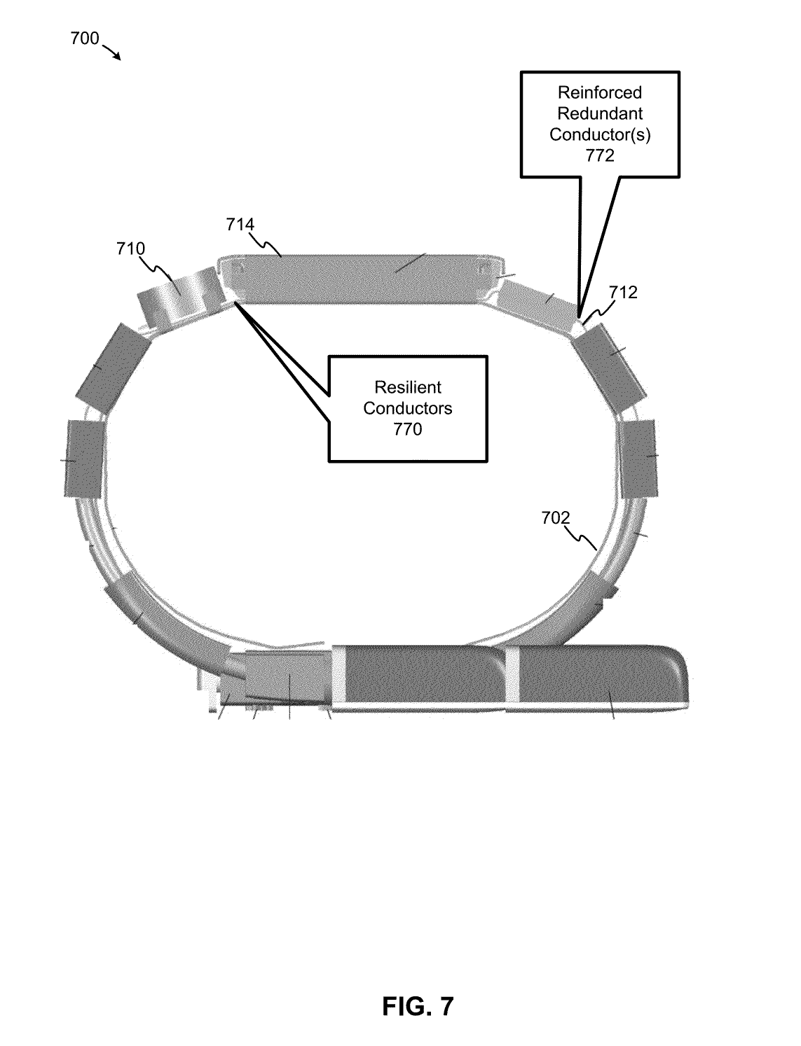

FIG. 7 is a diagram showing a side view of a flexible substrate including components coupled to a framework, according to some examples. Diagram 700 shows a flexible substrate 712 including reinforced redundant conductor 772 coupled to a framework 702. Flexible substrate 710 can include a number of components mounted thereupon including a vibratory motor 712, a battery 714, and the like. Further, resilient conductors 770 can be implemented to provide conductivity to vibratory motor 710, as well as conductivity to provide power from battery 714 to other components (not shown). In some cases, such components are mounted or otherwise coupled to flexible substrate 710 in a rigid region. In some examples, a component can be overmolded with a low pressure molding material.

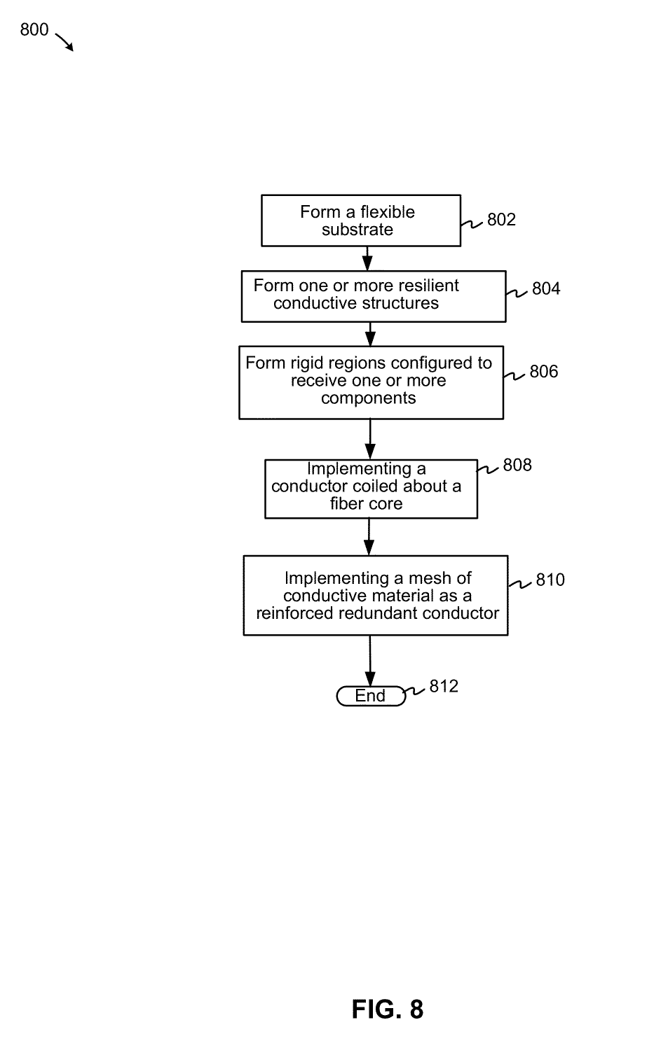

FIG. 8 is an example of a flow for implementing a flexible substrate including resilient conductive structures and/or reinforced redundant conductors, according to some embodiments. Flow diagram 800 is initiated at 802, at which a flexible substrate is formed. For example, one or more resilient conductive structures can be implemented at 804. At 806, a number of rigid regions can be formed to receive one or more components. At 808, a conductor can be wrapped about a fiber core to form a resilient conductive structure. At 810, a mesh of conductive material can be implemented as a reinforced redundant conductor. Flow 800 terminates at 812.

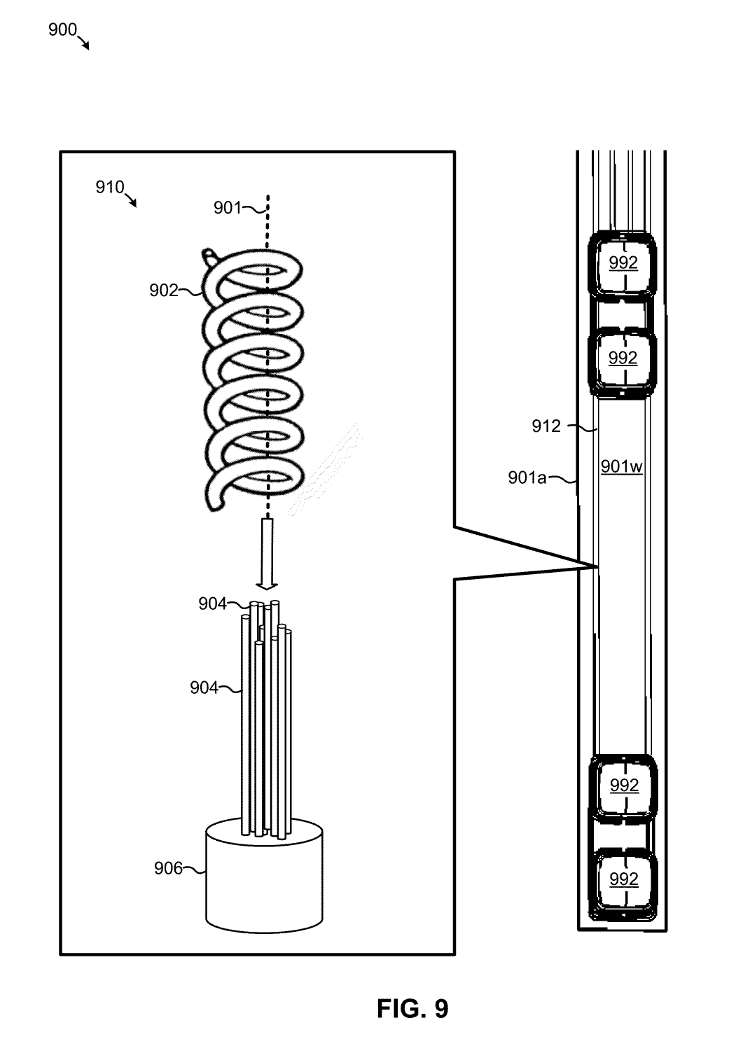

FIG. 9 is a diagram depicting of a flexible substrate implementing resilient conductive structures in an electrode bus, according to some examples. As shown, diagram 900 of FIG. 9 depicts an example of a resilient conductive structure 910 includes a conductor 902 configured to vary (e.g., in direction, distance, etc.) from a medial line 901 as conductor 902 traverses or otherwise extends a length of resilient conductive structure 910. Portions of conductor 902 can form portions of a coil conductor, as shown. Note that conductor 902 is not limited to a coil, but rather can have other shapes, and can be folded around medial line 901. Conductor 902 can be a foil conductor, a circular wire conductor, or a conductor having any other shape. Further, conducted 902 is formed or otherwise wrapped around a core (e.g., a non-conductive core) that can include a number of fibers 904. In some examples, fiber 904 can include Kevlar® fibers or Kevlar-like fibers, as well as Aramid fibers to enhance rigidity and reliability of resilient conductive structure 910. In some cases, conductor 902 can be composed of a tin-coated copper material. Optionally, conductor 902 and fibers 904 can be encapsulated in an insulation material 906, such as silicone rubber.

Further, resilient conductive structures 910 may implemented as conductors 912 to form an electrode wire bus 901a that includes electrodes 992 (e.g., bioimpedance, or “BI,” electrodes). Electrode or wire bus wire bus 901a, and components coupled therewith, may include a bus substrate 901w that may be made from a flexible and electrically non-conductive material including but not limited to a thermoplastic elastomer and rubber, for example. In one example, the elastomer material can include, for example, TPE or TPU, to form a flexible substrate in which Kevlar™-based conductors 912 may be encapsulated. In one example, the flexible bus substrate 901w is formed of TPE and has a hardness of approximately 85 to 95 Shore A (e.g., approximately 90 Shore A in some cases).

Examples of wearable devices and one or more components, including flexible substrates and/or resilient conductive structures, as well as electrodes, may be described in U.S. patent application Ser. No. 14/480,628 (ALI-516) filed on Sep. 8, 2014, which is herein incorporated by reference.

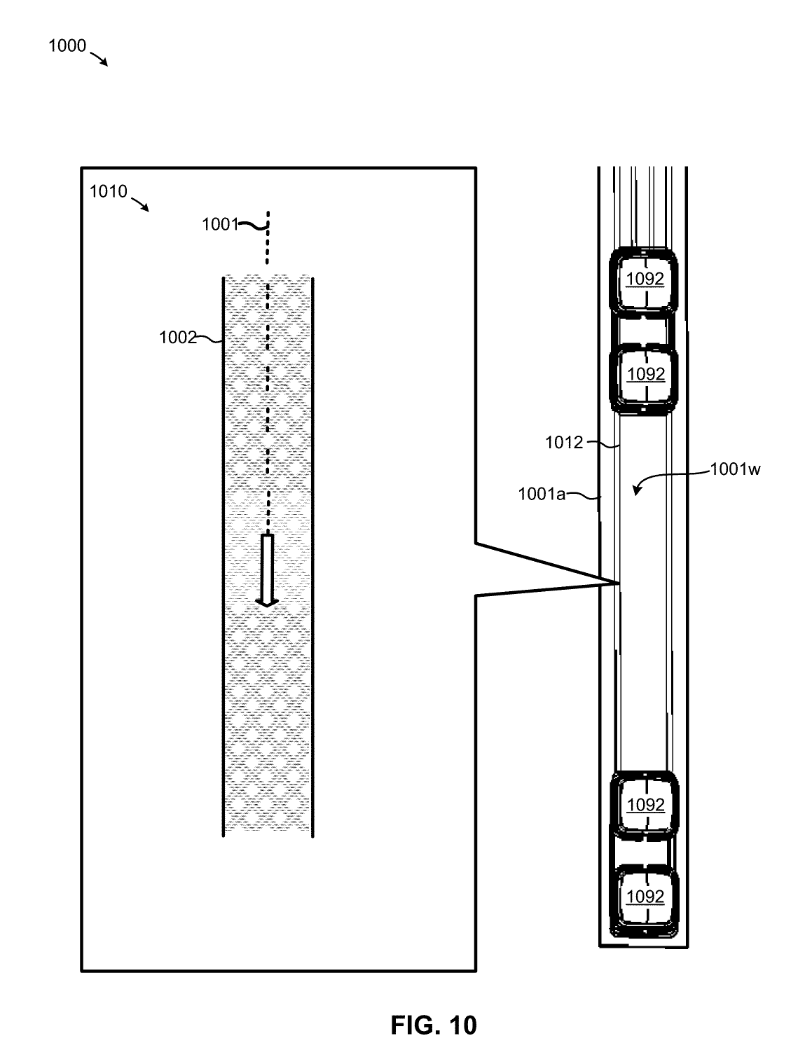

FIG. 10 is a diagram depicting of a flexible substrate implementing resilient conductive structures in an electrode bus, according to some examples. As shown, diagram 1000 of FIG. 10 depicts an example of a resilient conductive structure 1010 includes a conductor 1002 configured to vary (e.g., in direction, distance, etc.) from a medial line 1001 as conductor 1002 traverses or otherwise extends a length of resilient conductive structure 1010. Portions of conductor 1002 can form portions of a mesh conductor, as shown, and of similar structure and/or functionality as that described in connection with FIG. 5. Further, conducted 1002 may be formed or otherwise include a number of fibers (not shown), such as Kevlar® fibers or Kevlar-like fibers, as well as Aramid fibers to enhance rigidity and reliability of resilient conductive structure 1010. In some cases, conductor 1002 can be composed of a tin-coated copper material. Optionally, conductor 1002 and fibers can be encapsulated in an insulation material, such as silicone rubber.

Further, resilient conductive structures 1010 may implemented as conductors 1012 to form an electrode wire bus 1001a that includes electrodes 1092 (e.g., bioimpedance, or “BI,” electrodes). Electrode or wire bus wire bus 1001a, and components coupled therewith, may include a bus substrate 1001w that may be made from a flexible and electrically non-conductive material including but not limited to a thermoplastic elastomer and rubber, for example. In one example, the elastomer material can include, for example, TPE or TPU, to form a flexible substrate in which Kevlar™-based conductors 1012 may be encapsulated. In one example, the flexible bus substrate 1001w is formed of TPE.

Examples of wearable devices and one or more components, including flexible substrates and/or resilient conductive structures, as well as electrodes, may be described in U.S. patent application Ser. No. 14/480,628 (ALI-516) filed on Sep. 8, 2014, which is herein incorporated by reference.

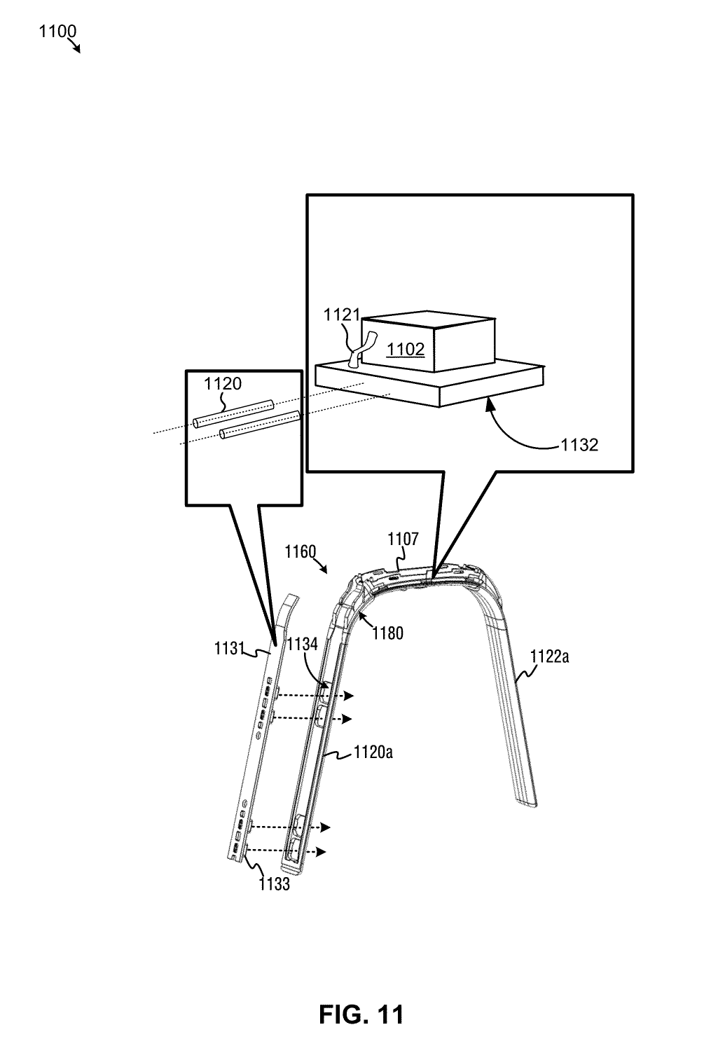

FIG. 11 is a diagram depicting an example of a wearable device implementing resilient conductive structures, according to some embodiments. Diagram 1100 depicts an intermediate assembly structure formed in molding process, according to some examples. Consider that cradle 1107 is placed in a mold for forming straps (e.g., strap bands and bands) for a wearable device. As shown, cradle 1107 may be integrated with an inner strap portion 1120a and an inner strap portion 1122a. Inner strap portion 1120a is secured to an anchor portion at an interface 1180, whereby the interface materials of the anchor portion form relatively secure physical and chemical bonds. Similarly, inner strap portion 1122a is secured to the other anchor portion and at an interface 1182.

According to some embodiments, the interface materials that form the anchor portions can include, but are not limited to, polycarbonate materials, or other like materials. Polycarbonate may provide an interface to couple metal cradle 1107 to an elastomer material used to form inner portions 1120a and 1122a. Thus, an interface materials, such as polycarbonate, bridges the difficulties of bonding metal and elastomers together in some cases. Anchor portions can be formed using polycarbonate molding techniques. According to some embodiments, an elastomer material may be a thermoplastic elastomer (“TPE”). In one embodiment, elastomer includes a thermoplastic polyurethane (“TPU”) material. In some examples, the elastomer has a hardness in a range of 58 to 72 Shore A. In one case, the lesser has a hardness in a range of 60 to 70 Shore A. An example of an elastomer is a GLS Thermoplastic Elastomer Versaflex™ CE Series CE 3620 by PolyOne of Ohio, USA.

Note further that apertures 1134 in inner portion 1120a may be formed by a mold. Apertures 1134 can be for receiving electrodes 1133 of an assembly of an electrode bus 1131 in a molded inner portion 1120a. As shown, electrode bus 1131 includes electrodes 1133, which are inserted through corresponding apertures 1134 prior to a molding step (e.g., a second shot). According to some embodiments, an elastomer material, such as TPE or TPU, may be used to form a flexible substrate in which Kevlar™-based conductors 1120 are encapsulated. In one example, the flexible substrate is formed of TPE and has a hardness of approximately 85 to 95 Shore A (e.g., about 90 Shore A). As such, resilient conductors may be disposed in electrode bus 1131 to facilitate formation of bioimpedance and/or GSR electrodes in a wrist-based wearable device.

Also, a rigid region may include a substrate 1132 to which resilient conductive structures 1120 couple to electrodes 1133 to communicate data and/or bioimpedance signals. In some examples, resilient conductive structures 1121 can couple a device 1102 to a rigid region 1132, which can include conductive paths, other devices, and/or circuitry. As depicted in diagram 1100, a rigid region including substrate 1132 and/or device 1102 (e.g., logic or circuitry, such a bioimpedance circuitry) may be disposed in a portion of a framework implemented as cradle 1107, which may form a constituent part of a wearable device. In other examples, framework 1107 can be configured to be formed in any shape, such as an ellipse, a circle, and/or in a helical shape, so that the wearable device can be worn around a wrist or other appendage of a user. A bioimpedance sensor may include one or more of bioimpedance circuitry, electrodes, and resilient conductive structures. Note that a pair of electrodes 1133 may be positioned in the flexible substrate to be adjacent to a blood vessel when worn on a wrist.

Examples of wearable devices and one or more components, including flexible substrates and/or resilient conductive structures, as well as electrodes and electrode positioning, may be described in U.S. patent application Ser. No. 14/480,628 (ALI-516) filed on Sep. 8, 2014, which is herein incorporated by reference.

In view of the foregoing, the structures and/or functionalities of resilient conductive structures and their constituent structures can enhance the reliability of a wearable device, especially when coupled to devices that experience vibrations, such as a vibratory motor, or other portions of the flexible substrate that receive relatively higher amounts of stress and/or forces. Further, reinforced redundant conductors implemented as described above can enhance reliability of a wearable device by providing redundant conductors and reinforcing a particular conductor to maintain connectivity while experiencing a relative amount of stress. Such a conductor can also provide a buffer for other conductors against stresses that might cause stress fractures.

Although the foregoing examples have been described in some detail for purposes of clarity of understanding, the above-described inventive techniques are not limited to the details provided. There are many alternative ways of implementing the above-described invention techniques. The disclosed examples are illustrative and not restrictive.

1. A wearable device comprising:
a framework configured to be worn or attached; and
a flexible substrate coupled to the framework, the flexible substrate having a first end and a second end and comprising:
one or more resilient conductive structures; and
one or more rigid regions configured to receive one or more components including a sensor, at least one component in a rigid region being coupled via the one or more resilient conductive structures.

2. The wearable device of claim 1 wherein the one or more resilient conductive structures each comprises:
a conductor traversing along a length of a resilient conductive structure,
wherein portions of the conductor vary from a medial line.

3. The wearable device of claim 2 wherein the portions of the conductor comprise:
portions of a coiled conductor.

4. The wearable device of claim 2 further comprising:
a non-conductive core around which the conductor encompasses.

5. The wearable device of claim 4 wherein the non-conductive core comprises:
a plurality of fibers.

6. The wearable device of claim 2 further comprising:
multiple other conductors traversing the length of the resilient conductive structure to provide connective redundancy for the conductor.

7. The wearable device of claim 1 further comprising:
a reinforced redundant conductor.

8. The wearable device of claim 7 wherein the reinforced redundant conductor comprises:
a mesh of conductive material.

9. The wearable device of claim 7 wherein the reinforced redundant conductor is disposed at an edge of the flexible substrate, the reinforced redundant conductor extending from the rigid region to another rigid region.

10. The wearable device of claim 1 further comprising:
a vibratory motor coupled to the one or more resilient conductive structures.

11. The wearable device of claim 1 further comprising:
a battery coupled to the one or more resilient conductive structures.

12. The wearable device of claim 1 wherein the flexible substrate comprises:
bioimpedance electrodes.

13. The wearable device of claim 12 further comprising:
a bioimpedance circuit coupled to via at least one resilient conductive structure to at least one bioimpedance electrode.

14. The wearable device of claim 12 further comprising:
an electrode bus.

15. The wearable device of claim 1 wherein the flexible substrate comprises:
a pair of electrodes positioned in the flexible substrate to be adjacent to a blood vessel when worn on a wrist.

16. A method comprising:
forming a flexible substrate including:
one or more resilient conductive structures; and
rigid regions configured to receive one or more components including a sensor, at least two rigid regions coupled via the one or more resilient conductive structures,
wherein the flexible substrate includes rigid regions configured to receive one or more components including a vibratory motor.

17. The method of claim 16, further comprising:
implementing a conductor coiled about a fiber core.

18. The method of claim 16, further comprising:
implementing a mesh of conductive material as a reinforced redundant conductor.
